(19) United States
(12) Patent Application Publication
(10) Pub. No.: US 2013/0175958 A1
(43) Pub. Date: Jul. 11, 2013

(54) SYSTEMS AND METHODS FOR TRANSMITTING AND/OR UTILIZING HVDC POWER IN A SUBMARINE ENVIRONMENT

(71) Applicants: Samuel T. McJunkin, Houston, TX (US); Robert J. Appleby, Houston, TX (US)

(72) Inventors: Samuel T. McJunkin, Houston, TX (US); Robert J. Appleby, Houston, TX (US)

(21) Appl. No.: 13/542,483

(22) Filed: Jul. 5, 2012

Related U.S. Application Data
(60) Provisional application No. 61/515,212, filed on Aug. 4, 2011.

(51) Int. Cl. F16L 55/00; H05K 7/20; H02P 27/06; H05K 5/06

(52) U.S. Cl. CPC F16L 55/00; H05K 5/069; H05K 7/20218; H02P 27/06
USPC 318/400.26; 138/103; 361/679.01; 361/701

(57) ABSTRACT

Systems and methods for transmitting and/or utilizing high voltage DC (HVDC) electric current in a submarine environment. The systems and methods may include the use of a submarine hydrocarbon pipeline to transmit both the HVDC electric current and a fluid stream. The systems and methods also may include the use of the HVDC electric current to do mechanical work within the submarine environment. Additionally or alternatively, the systems and methods may use a pressure-compensated electronics apparatus (PCEA) to receive the HVDC electric current and to produce a conditioned electric current therefrom. The systems and methods further may include controlling a pressure within the PCEA, controlling a temperature of electronic equipment contained within the PCEA, providing the conditioned electric current to a submarine energy consuming device, controlling the operation of the submarine energy consuming device, and/or producing, processing, and/or transmitting hydrocarbons with the submarine energy consuming device.

### CROSS-REFERENCE TO RELATED APPLICATION

This application claims the priority benefit of U.S. Provisional Patent Application 61/515,212 filed Aug. 4, 2011 entitled Systems and METHODS FOR TRANSMITTING AND/OR UTILIZING HVDC POWER IN A SUBMARINE ENVIRONMENT the entirety of which is incorporated by reference herein.

### FIELD OF THE DISCLOSURE

The present disclosure is directed to systems and methods for transmitting and/or utilizing High Voltage DC (HVDC) power in a submarine environment, and more particularly to systems and methods for transmitting and/or utilizing HVDC to produce and/or provide a motive force for the transmission of hydrocarbons in the submarine environment.

### BACKGROUND OF THE DISCLOSURE

As the oil and gas industry explores, develops, produces, and transports hydrocarbons from deeper and more remote submarine hydrocarbon reserves, the transmission of large amounts of electrical power over long distances in a submarine environment becomes increasingly important. Subsea processing systems for the production and/or transport of hydrocarbons may utilize a large number of electric motors to power subsea equipment such as pumps and compressors, with each electric motor consuming several megawatts (MW) of electrical power. With multiple pumps, compressors, and/or booster units being utilized for each subsea processing system, energy requirements may run as high as several hundred megawatts.

Conventionally, electrical power is transmitted over land using alternating current (AC) electrical current, which may provide for relatively straightforward conversion from the high voltage that is carried by the power transmission lines to the relatively lower voltage that is utilized by the end user. However, the transmission of AC electric current over long distances in a submarine environment poses several unique challenges due to constraints related to the size of the transmission line, or cable, that may be utilized and/or additional equipment that may be needed to stabilize electrical loads.

As an illustrative example, submarine AC power transmission lines must contend with reactive power, which is not available to do work at the electrical load but which must be provided by a power source and which is conducted by the electrical transmission lines. As a result, a submarine AC power transmission system will tend to have a decreased overall efficiency and/or require transmission lines of increased size. This decreased efficiency and/or increased transmission line size may be significant and may limit economic development and/or production of hydrocarbons from certain hydrocarbon reserves.

HVDC electric current may be transmitted in a submarine environment without the need to contend with the reactive power issues associated with AC power transmission. However, the HVDC often must be inverted to produce AC electric current in order to efficiently perform useful mechanical work in a submarine environment. In addition, while the lack of reactive power issues when transmitting HVDC electric current in a submarine environment may provide for the use of smaller and/or less expensive electrical transmission lines, the cost of these transmission lines is still significant.

### SUMMARY OF THE DISCLOSURE

Systems and methods for transmitting and/or utilizing high voltage DC (HVDC) electric current in a submarine environment. These systems and methods may include the use of a submarine hydrocarbon pipeline to transmit both the HVDC electric current and a fluid stream. These systems and methods also may include the use of the HVDC electric current to do mechanical work within the submarine environment. Additionally or alternatively, these systems and methods may include the use of a pressure-compensated electronics apparatus (PCEA) to receive the HVDC electric current and to produce a conditioned electric current therefrom. These systems and methods further may include controlling a pressure within the PCEA, controlling a temperature of electronic equipment contained within the PCEA, providing the conditioned electric current to a submarine energy consuming device, controlling the operation of the submarine energy consuming device, and/or producing, processing, and/or transmitting hydrocarbons with the submarine energy consuming device and/or the submarine hydrocarbon pipeline.

In some embodiments, the submarine hydrocarbon pipeline may include thermal insulation configured to decrease heat transfer between the fluid stream and the submarine environment. In some embodiments, the submarine hydrocarbon pipeline may include a water barrier configured to provide a barrier for contact between water and at least a portion of the submarine hydrocarbon pipeline. In some embodiments, the submarine hydrocarbon pipeline may include an abrasion resistant layer configured to protect an external surface of the submarine hydrocarbon pipeline. In some embodiments, the submarine hydrocarbon pipeline may include external electrical insulation configured to limit a flow of electric current between the submarine hydrocarbon pipeline and the submarine environment. In some embodiments, the submarine hydrocarbon pipeline may include internal electrical insulation configured to limit a flow of electric current between the submarine hydrocarbon pipeline and the fluid stream. In some embodiments, the internal electrical insulation may be present on an entire inner surface of the submarine hydrocarbon pipeline. In some embodiments, the internal electrical insulation may be present on a selected portion of the inner surface of the submarine hydrocarbon pipeline. In some embodiments, the submarine hydrocarbon pipeline may include a fluid conduit. In some embodiments, the submarine hydrocarbon pipeline may include an electrical conduit.

In some embodiments, the PCEA may include and/or contain electronic equipment. In some embodiments, the electronic equipment may be configured to receive the HVDC electric current from the submarine hydrocarbon pipeline and to produce the conditioned electric current therefrom. In some embodiments, the PCEA may include a pressure compensation system. In some embodiments, the pressure compensation system may be configured to decrease a pressure differential between an interior of the PCEA and an exterior of the PCEA. In some embodiments, the pressure compensation system may include a variable volume device. In some embodiments, the PCEA also may include a thermal management system. In some embodiments, the thermal management system may be configured to control a temperature of a portion of an internal volume of the PCEA and/or a temperature of the electronic equipment.

### BRIEF DESCRIPTION OF THE DRAWINGS

FIG. 1 is a schematic representation of an illustrative, non-exclusive example of a submarine power distribution system according to the present disclosure.

FIG. 2 is a less schematic representation of an illustrative, non-exclusive example of a submarine power distribution system according to the present disclosure.

FIG. 3 is a schematic representation of an illustrative, non-exclusive example of a pressure-compensated electronics apparatus according to the present disclosure.

FIG. 4 is schematic representation of a DC to AC inverter that may be utilized with the pressure-compensated electronics apparatus according to the present disclosure.

FIG. 5 is a schematic representation of an illustrative, non-exclusive example of a submarine hydrocarbon pipeline according to the present disclosure.

FIG. 6 is a schematic cross-sectional view of the submarine hydrocarbon pipeline of FIG. 5 taken along plane 6-6.

FIG. 7 is a schematic cross-sectional view of the submarine hydrocarbon pipeline of FIG. 5 taken along plane 7-7.

FIG. 8 is another schematic representation of an illustrative, non-exclusive example of a submarine hydrocarbon pipeline according to the present disclosure.

FIG. 9 is a flowchart depicting methods according to the present disclosure for utilizing HVDC electric current in a submarine environment.

### DETAILED DESCRIPTION AND BEST MODE OF THE DISCLOSURE

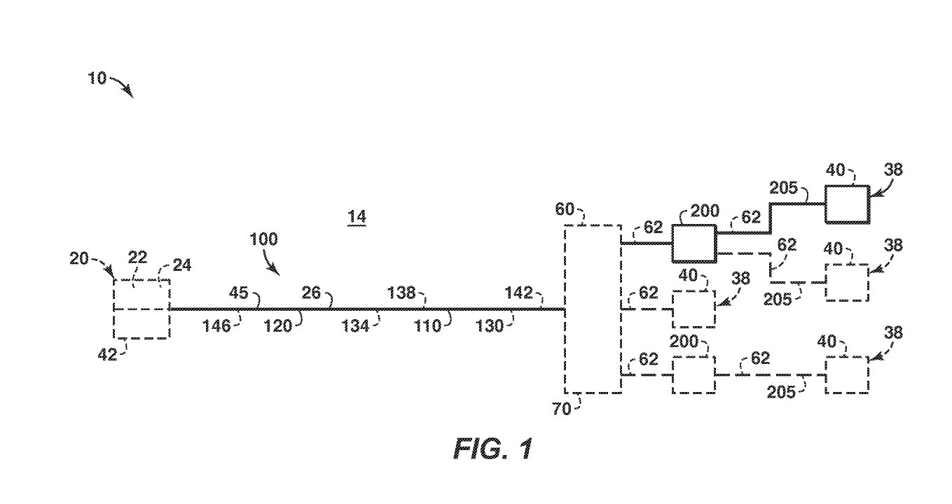

FIG. 1 provides a schematic view of an illustrative, non-exclusive example of submarine power distribution systems 10 according to the present disclosure. Submarine power distribution system 10 includes a submarine hydrocarbon pipeline 100 that is configured to transmit, conduct, supply, or otherwise provide an electric conduit for the flow of electric current 26 from an electric current source 20 to one or more submarine energy consuming devices 38, such as one or more pieces of hydrocarbon recovery equipment 40. Submarine hydrocarbon pipeline 100 also is configured to receive, transmit, transport, produce, or otherwise provide a fluid pathway and/or a fluid conduit for a flow of a fluid stream 45 from and/or between submarine energy consuming device 38 and upstream device 42.

As shown in FIG. 1, it is within the scope of the present disclosure that submarine power distribution system 10 also may include and/or be in fluid communication with one or more fluid distribution modules 60 that are configured to collect fluid provided by submarine energy consuming device 38 and supply the collected fluid to upstream device 42 through submarine hydrocarbon pipeline 100 as fluid stream 45. Additionally or alternatively, it is also within the scope of the present disclosure that submarine power distribution system 10 also may include and/or be in electrical communication with one or more current distribution modules 70 that are configured to provide electric current 26 from electric current source 20 that is supplied by submarine hydrocarbon pipeline 100 to submarine energy consuming device 38. Additionally or alternatively, submarine power distribution system 10 also may include and/or be in electrical communication with one or more pressure-compensated electronics apparatus 200 that are configured to receive electric current 26 from submarine hydrocarbon pipeline 100 and to supply a conditioned electric current 205 to submarine energy consuming device 38.

At least a portion of submarine power distribution system 10 according to the present disclosure may be located within a submarine environment 14. As an illustrative, non-exclusive example, at least a portion of submarine hydrocarbon pipeline 100, fluid distribution module 60, current distribution module 70, PCEA 200 and/or submarine energy consuming device 38 may be located within submarine environment 14. Additionally or alternatively, a substantial portion, a majority, and/or all of at least one of submarine hydrocarbon pipeline 100, fluid distribution module 60, current distribution module 70, PCEA 200, and/or submarine energy consuming device 38 may be located within the submarine environment.

Electric current source 20 may include any suitable source of electric current 26. This may include any suitable AC electric current source 22 and/or any suitable DC electric current source 24. Illustrative, non-exclusive examples of AC electric current sources 22 according to the present disclosure include any suitable electric utility grid and/or generator. Illustrative, non-exclusive examples of DC electric current sources 24 according to the present disclosure include any suitable generator and/or rectified AC electric current source.

It is within the scope of the present disclosure that electric current source 20 may include and/or be in electrical communication with any suitable electrical power conditioning equipment, illustrative, non-exclusive examples of which include any suitable transformer, buck transformer, boost transformer, rectifier, diode, capacitor, inductor, transistor, and/or electrical switch. It is also within the scope of the present disclosure that electric current source 20 may be located, or sited, at any suitable location, illustrative, non-exclusive examples of which include any suitable land-based location, any suitable ship-based location, and/or any suitable marine platform-based location.

AC electric current source 22 may include a source of high voltage AC (HVAC) electric current and also may be referred to as HVAC electric current source 22. Similarly, DC electric current source 24 may include a source of high voltage DC (HVDC) electric current and also may be referred to as HVDC electric current source 24.

As used herein, high voltage is a relative term that may refer to a voltage that is greater than a low or medium voltage. Illustrative, non-exclusive examples of high voltages according to the present disclosure include voltages of greater than 0.5 kilovolts (kV), including voltages of at least 1 kV, at least 1.5 kV, at least 2 kV, at least 5 kV, at least 10 kV, at least 25 kV, at least 50 kV, at least 75 kV, at least 100 kV, at least 150 kV, at least 200 kV, at least 250 kV, at least 300 kV, at least 350 kV, at least 400 kV, at least 450 kV, at least 500 kV, or at least 750 kV. When electric current source 20 includes an HVAC electric current source 22, electric current 26 also may be referred to as HVAC electric current 26. Similarly, when electric current source 20 includes HVDC electric current source 24, electric current 26 also may be referred to as HVDC electric current 26. When electric current 26 includes HVDC electric current 26, it is within the scope of the present disclosure that the voltage of the HVDC electric current may be sufficient to inhibit corrosion of the corresponding submarine hydrocarbon pipeline 100 within submarine environment 14.

A magnitude of electric current 26 may be sufficient to generate resistive heating within submarine hydrocarbon pipeline 100. As an illustrative, non-exclusive example, it is within the scope of the present disclosure that this resistive heating may be sufficient in magnitude to counteract, balance, or otherwise inhibit heat loss from fluid stream 45 to submarine environment 14. As another illustrative, non-exclusive example, it is also within the scope of the present disclosure that this resistive heating may be sufficient in magnitude to maintain a temperature of fluid stream 45 above a threshold temperature.

A power of the electric current that is transmitted by submarine hydrocarbon pipeline 100 may be above a threshold power level and/or within a threshold range of power levels. As an illustrative, non-exclusive example, it is within the scope of the present disclosure that the power of the electric current may be at least 10 megawatts (MW), at least 15 MW, at least 20 MW, at least 30 MW, at least 40 MW, at least 50 MW, at least 75 MW, at least 100 MW, at least 150 MW, at least 200 MW, 20-50 MW, 100-200 MW, 10-300 MW, and/or 50-150 MW, though power levels of greater than 300 MW, as well as power levels of less than 10 MW, also are within the scope of the present disclosure.

Submarine hydrocarbon pipeline 100, which also may be referred to as submarine tieback 100 and/or subsea tieback 100, may include any suitable fluid conduit 110 that is configured to provide a fluid pathway for receiving, supplying, transmitting, transporting, or otherwise producing fluid stream 45 from hydrocarbon recovery equipment 40 to upstream device 42 and/or receiving, supplying, transmitting, transporting, or otherwise producing fluid stream 45 from upstream device 42 to hydrocarbon recovery equipment 40. This may include any suitable fluid conduit, pipe, pipeline, hydrocarbon pipeline, oil pipeline, and/or natural gas pipeline. In addition, fluid conduit 110 of submarine hydrocarbon pipeline 100 also is configured to provide an electrical conduit 120 that is configured to transmit, conduct, supply, or otherwise provide electric current 26 from electric current source 20 to submarine energy consuming device 38.

It is within the scope of the present disclosure that submarine hydrocarbon pipeline 100 may include, may be coated with, may be operatively attached to, and/or may be covered by any suitable coating, wrap, cloth, sheath, layer, covering, encapsulation, and/or barrier. This may include any suitable electrical insulation 130, any suitable thermal insulation 134, any suitable water or other fluid barrier 138, any suitable abrasion barrier 142, and/or any suitable corrosion barrier 146.

Illustrative, non-exclusive examples of electrical insulation 130 according to the present disclosure include any suitable non-electrically conductive covering, sheath, and/or coating that may be constructed of any suitable material, illustrative, non-exclusive examples of which include any suitable polymer, elastomer, glass, fiberglass, ceramic, polyethylene, polypropylene, epoxy, and/or fusion-bonded epoxy. Illustrative, non-exclusive examples of thermal insulation 134 include any suitable glass and/or polymer-based thermally insulating covering, coating, and/or sheath. Illustrative, non-exclusive examples of fluid barrier 138 according to the present disclosure include any suitable barrier to fluid (including, but not limited to) water migration, including a lead sheath. Illustrative, non-exclusive examples of abrasion barrier 142 according to the present disclosure include any suitable polymeric coating, covering, and/or sheath, including a polyethylene sheath. Illustrative, non-exclusive examples of corrosion barrier 146 according to the present disclosure include any suitable corrosion-resistant coating, including paints, oxides, and/or epoxies.

Submarine hydrocarbon pipeline 100 may include any suitable length. As an illustrative, non-exclusive example, it is within the scope of the present disclosure that submarine hydrocarbon pipeline 100 may be at least 50 kilometers (km) long, at least 75 km long, at least 80 km long, at least 100 km long, at least 150 km long, at least 200 km long, at least 250 km long, at least 300 km long, at least 350 km long, at least 400 km long, at least 450 km long, or at least 500 km long, although lengths of less than 50 km, as well as lengths of greater than 500 km are also within the scope of the present disclosure.

It is within the scope of the present disclosure that any suitable length, or portion, of submarine hydrocarbon pipeline 100 may be located under water and/or may be contained within submarine environment 14. As an illustrative, non-exclusive example, at least a portion, a substantial portion, a majority, at least 50%, at least 60%, at least 70%, at least 80%, at least 90%, at least 95%, at least 99%, at least 99.5%, or at least 99.9% of a length of the submarine hydrocarbon pipeline may be located under water and/or may be contained within the submarine environment.

Fluid conduit 110 may include any suitable structure configured to provide a fluid pathway for fluid stream 45. As an illustrative, non-exclusive example, fluid conduit 110 may include a metallic pipe. As another illustrative, non-exclusive example, fluid conduit 110 may include a hydrocarbon pipeline configured to transport hydrocarbons. Electrical conduit 120 may include any suitable structure configured to provide an electrical conduit for electric current 26. Similar to the illustrative, non-exclusive examples of fluid conduit 110, electrical conduit 120 may include a metallic pipe and/or a hydrocarbon pipeline.

When present, fluid distribution module 60 may include any suitable structure that is configured to collect, mix, and/or otherwise combine one or more recovery equipment fluid streams 62 into fluid stream 45 and/or to separate, distribute, and/or otherwise divide fluid stream 45 into recovery equipment fluid streams 62. Illustrative, non-exclusive examples of fluid distribution modules 60 according to the present disclosure include any suitable manifold, valve, fitting, pipe, and/or fluid conduit.

When present, current distribution module 70 may include any suitable structure that is configured to provide at least a portion of electric current 26 to PCEA 200 and/or submarine energy consuming device 38. It is within the scope of the present disclosure that current distribution module 70 may include, or utilize, at least a portion of fluid distribution module 60 to provide electric current 26 to the PCEA and/or the submarine energy consuming device. As an illustrative, non-exclusive example, fluid distribution module 60 may include a metallic, or otherwise electrically conductive, fluid distribution module, and electric current 26 may be conducted through the electrically conductive components thereof

It is also within the scope of the present disclosure that at least a portion of current distribution module 70 may be separate, discrete, and/or otherwise distinct from fluid distribution module 60. As an illustrative, non-exclusive example, at least a portion of current distribution module 70 may include electrically conductive conduits, cables, and/or wires, together with any suitable passive and/or active electrical components that may be configured to conduct electric current 26 and which may be distinct and/or electrically isolated from at least a portion of fluid distribution module 60.

PCEA 200 includes any suitable structure configured to receive electric current 26 from submarine hydrocarbon pipeline 100 and/or current distribution module 70 and to produce conditioned electric current 205 therefrom. It is within the scope of the present disclosure that, as shown schematically in FIG. 1, submarine power distribution system 10 may include a plurality of PCEAs 200, including two, more than two, more than three, more than five, more than 10, more than 20, or more than 50 PCEAs.

When submarine power distribution system 10 includes a plurality of PCEAs, it is within the scope of the present disclosure that at least a portion of the plurality of PCEAs may be electrically connected in parallel to subsea hydrocarbon pipeline 100 and/or current distribution module 70. Additionally or alternatively, it is also within the scope of the present disclosure that at least a portion of the plurality of PCEAs may be electrically connected in series with one another and to subsea hydrocarbon pipeline 100 and/or current distribution module 70.

PCEA 200 according to the present disclosure may be configured to change, modify, or otherwise convert electric current 26 that is supplied thereto into a form that may be supplied to and/or utilized by submarine energy consuming device 38 as conditioned electric current 205. As an illustrative, non-exclusive example, PCEA 200 may be configured to increase, decrease, or otherwise modify a voltage of electric current 26. As another illustrative, non-exclusive example, PCEA 200 may be configured to filter, or otherwise condition, electric current 26. As another illustrative, non-exclusive example, and when electric current 26 includes AC electric current 26, PCEA 200 may be configured to rectify the AC electric current to produce a DC electric current. As another illustrative, non-exclusive example, and when electric current 26 includes AC electric current 26, PCEA 200 may be configured to control, change, modify, increase, and/or decrease a frequency of the AC electric current, which may in turn control, change, modify, increase, and/or decrease a rotational frequency of an electric motor that is configured to receive the AC electric current. As another illustrative, non-exclusive example, and when electric current 26 includes DC electric current 26, PCEA 200 may be configured to invert the DC electric current to produce an AC electric current. Additionally, PCEA 200 may be configured to control, change, modify, increase, and/or decrease a frequency of the produced AC electric current, which may in turn control, change, modify, increase, and/or decrease a rotational frequency of an electric motor that is configured to receive the produced AC electric current.

Submarine energy consuming device 38 may include any suitable structure that is configured to consume at least a portion of electric current 26, including energy consuming devices that may consume the portion of electric current 26 to perform mechanical work, produce heat, and/or provide a motive force for a chemical reaction. It is within the scope of the present disclosure that energy consuming device 38 may perform mechanical work, produce heat, and/or provide a motive force for the chemical reaction at least partially and/or completely within the submarine environment. Additionally or alternatively, it is also within the scope of the present disclosure that submarine energy consuming device 38 may function in a remote and/or inaccessible location.

Illustrative, non-exclusive examples of remote locations include locations that are at least 1 km, at least 5 km, at least 10 km, at least 25 km, at least 50 km, at least 100 km, at least 250 km, at least 500 km, at least 1000 km, at least 1500 km, at least 2000 km, or at least 2500 km from at least one of a town, a city, a populated area, an industrial complex, and/or a manned facility that is in electrical and/or fluid communication with submarine hydrocarbon pipeline 100. Illustrative, non-exclusive examples of inaccessible locations according to the present disclosure include locations that are difficult to access, may be accessed only in certain times of the year, may be accessed only under certain weather conditions, may not be directly accessed by people, and/or that may require the use of specialized equipment in order to facilitate direct access by people, illustrative, non-exclusive examples of which include remote and/or deep submarine locations and/or arctic locations.

Illustrative, non-exclusive examples of energy consuming devices 38 according to the present disclosure include any suitable piece of hydrocarbon recovery equipment 40, such as hydrocarbon production equipment, hydrocarbon processing equipment, pumps, compressors, pressure boosters, electric motors, controllers, motor controllers, and/or sensors. It is within the scope of the present disclosure that submarine energy consuming device 38 may be configured to provide a motive force to fluid stream 45, such as for transmitting the fluid stream through submarine hydrocarbon pipeline 100 and/or fluid conduit 110. Additionally or alternatively, it is also within the scope of the present disclosure that submarine energy consuming device 38 may be configured to produce fluid stream 45 from a hydrocarbon reservoir and/or process fluid stream 45, such as to change a state, phase, temperature, pressure, and/or chemical composition of the fluid stream.

As shown in FIG. 1, it is within the scope of the present disclosure that submarine power distribution system 10 may include and/or be in electrical and/or fluid communication with a plurality of submarine energy consuming devices 38. As an illustrative, non-exclusive example, submarine hydrocarbon pipeline 100 and/or current distribution module 70 may provide electric current 26 directly to submarine energy consuming device 38. As another illustrative, non-exclusive example, submarine hydrocarbon pipeline 100 and/or current distribution module 70 may provide electric current 26 to PCEA 200, which may then provide conditioned electric current 205 to the submarine energy consuming device. It is within the scope of the present disclosure that each submarine energy consuming device 38 may receive conditioned electric current 205 from a single, dedicated PCEA. Additionally or alternatively, it is also within the scope of the present disclosure that a single PCEA may provide conditioned electric current 205 to a plurality of submarine energy consuming devices 38 and/or that a single submarine energy consuming device 38 may receive conditioned electric current 205 from a plurality of PCEAs 200.

Fluid stream 45 may include any suitable fluid that may flow through and/or be processed by submarine energy consuming device 38, hydrocarbon recovery equipment 40, upstream device 42, fluid distribution module 60, and/or submarine hydrocarbon pipeline 100. Illustrative, non-exclusive examples of fluid stream 45 according to the present disclosure include any suitable liquid, gas, and/or slurry, including a hydrocarbon, oil, natural gas, liquefied natural gas, and/or water.

Upstream device 42 may include any suitable device and/or structure that is configured to receive fluid stream 45 from submarine hydrocarbon pipeline 100 and/or supply fluid stream 45 to submarine hydrocarbon pipeline 100. This may include any suitable hydrocarbon processing equipment, hydrocarbon refining equipment, hydrocarbon storage device, hydrocarbon transportation device, pump, compressor, and/or refinery. It is within the scope of the present disclosure that at least a portion of upstream device 42 may be located on land, on a ship, on a sea-based platform, and/or in the submarine environment.

Upstream device 42 may be separate from electric current source 20; however, it is also within the scope of the present disclosure that upstream device 42 may be housed with, located proximal to, and/or form a portion of electric current source 20. As an illustrative, non-exclusive example, upstream device 42 and electric current source 20 may be housed within the same structure, contained within the same vessel, and/or present on the same sea-based platform. It is also within the scope of the present disclosure that submarine power distribution system 10 may include or be in communication with additional valves, fittings, conduits, electrical cables, and/or other system components that may provide fluid and/or electrical communication among upstream device 42, electric current source 20, submarine hydrocarbon pipeline 100, submarine energy consuming device 38, and/or hydrocarbon recovery equipment 40.

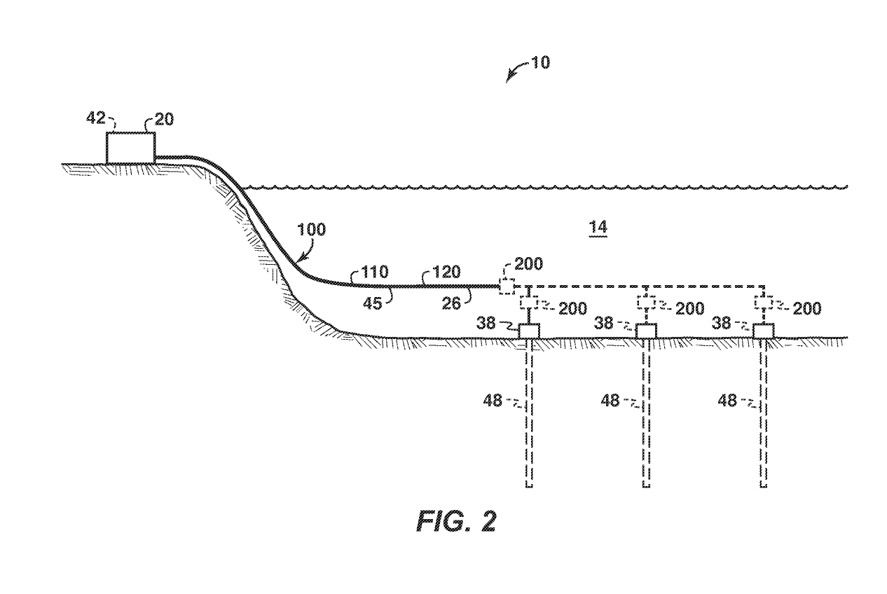

Submarine environment 14 refers to an underwater environment. Generally, underwater environments according to the present disclosure include environments that are under the surface of large bodies of water, such as oceans and/or seas; however environments that are under the surface of smaller bodies of water, such as lakes, ponds, rivers, bays, marshes, and/or streams are also within the scope of the present disclosure. It is also within the scope of the present disclosure that a submarine environment may extend under the surface of one or more larger and one or more smaller bodies of water. As an illustrative, non-exclusive example, and when at least a portion of submarine power distribution system 10 is located under the surface of a sea, submarine environment 14 also may be referred to as subsea environment 14. As another illustrative, non-exclusive example, and when at least a portion of submarine power distribution system 10 is located under the surface of an ocean, submarine environment 14 also may be referred to as subocean environment 14. It is within the scope of the present disclosure that submarine environment 14 may include saltwater and/or freshwater. Although not required to all embodiments, a submarine environment in which submarine power distribution system 10 is utilized typically will include at least a portion, if not a majority, substantial, or complete portion thereof, that is remote from land, deep, or otherwise difficult to access. FIG. 2 provides a less schematic but still illustrative, non-exclusive example of submarine power distribution systems 10 according to the present disclosure. FIG. 2 may include land-based electric current source 20 and land-based upstream device 42, as well as one or more PCEAs 200, submarine energy consuming devices 38, and/or hydrocarbon wells 48 that are located in submarine environment 14. Similar to FIG. 1, submarine hydrocarbon pipeline 100 may provide fluid conduit 110 for fluid stream 45 and electrical conduit 120 for electric current 26 to be transmitted between electric current source 20, upstream device 42, PCEA 200, and/or submarine energy consuming devices 38.

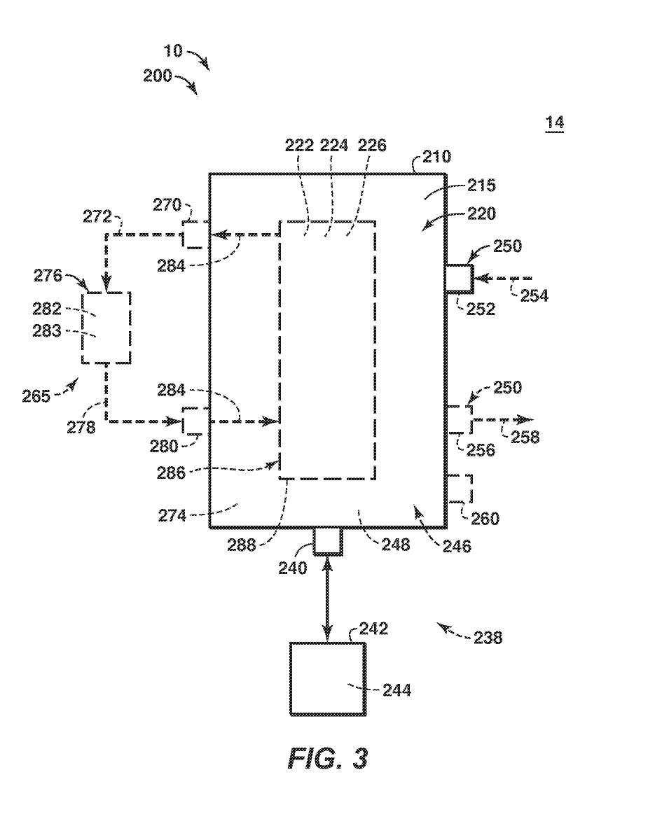

FIG. 3 provides a schematic representation of an illustrative, non-exclusive example of PCEA 200 according to the present disclosure. PCEA 200 may be designed, configured, or otherwise constructed for use in submarine environment 14 and also may be referred to as marinised PCEA 200. Thus, PCEA 200 may include materials and/or methods of construction that are compatible with use in the submarine environment, such as inert materials, water-resistant materials, corrosion-resistant materials, and/or pressure-resistant materials. It is also within the scope of the present disclosure that PCEA 200 may include a modular PCEA that is configured to be readily installed, readily repaired, and/or readily replaced while in the submarine environment.

In FIG. 3, PCEA 200 includes external shell 210 that defines an internal volume 215, which contains or includes electronic equipment 220. PCEA 200 further includes or is associated with a pressure compensation system 238 and at least one electrical port 250. It is within the scope of the present disclosure that electrical port 250 may include at least one input electrical port 252 that is configured to receive input electrical signal 254 into internal volume 215 of PCEA 200. It is also within the scope of the present disclosure that PCEA 200 also may include at least one output electrical port 256 that is configured to provide output electrical signal 258 from internal volume 215 of the PCEA and/or that input electrical port 252 and output electrical port 256 may form a portion of a single electrical port 250. PCEA 200 also may include one or more communication ports 260. It is further within the scope of the present disclosure that PCEA 200 may include or be in fluid communication with a thermal management system 265 that is configured to control a temperature of at least a portion of PCEA 200, electronic equipment 220, and/or internal volume 215.

External shell 210 may include any suitable structure that is configured to house, contain, or otherwise define internal volume 215. Illustrative, non-exclusive examples of external shells 210 according to the present disclosure include any suitable vessel, pressure vessel, container, and/or structure constructed from any suitable material, illustrative, non-exclusive examples of which include any suitable metal, plastic, polymer, fiberglass, and/or composite. It is within the scope of the present disclosure that external shell 210 may be configured to be fluid-tight, to form a barrier for the flow of fluid between internal volume 215 and an exterior of the external shell, and/or to isolate internal volume 215 from fluid communication with the exterior of the external shell. Thus, external shell 210 also may be referred to as fluid-tight external shell 210 and/or isolating shell 210.

Electronic equipment 220 may include any suitable electrical components that may perform a desired electrical operation. Illustrative, non-exclusive examples of electronic equipment 220 according to the present disclosure include any suitable capacitor, diode, resistor, inductor, transistor, electrical switch, solid state electrical switch, DC to AC inverter 222, AC motor driver, AC motor speed controller 224, variable frequency drive, adjustable speed drive, variable speed drive, and/or vector drive. Electronic equipment 220 also may include any suitable controller 226, illustrative, non-exclusive examples of which include a controller that is configured to control the operation of at least a portion of the other components of electronic equipment 220 and/or a controller that is configured to control the operation of submarine energy consuming device 38 and/or hydrocarbon recovery equipment 40 of FIGS. 1 and 2.

Input electrical signal 254 may include any suitable electrical signal that is configured to be supplied to, provide power to, provide communication with, and/or interact with PCEA 200 and/or electronic equipment 220. As an illustrative, non-exclusive example, input electrical signal 254 may include electric current 26, AC electric current 26, HVAC electric current 26, DC electric current 26, and/or HVDC electric current 26 of FIGS. 1-2. Similarly, output electric signal 258 may include any suitable electrical signal configured to be produced from, provide power from, and/or provide communication from PCEA 200 and/or electronic equipment 220 to a device that is external to internal volume 215. As an illustrative, non-exclusive example, and with reference to FIGS. 1 and 2, output electric signal 258 may include conditioned electric current 205 that is configured to provide power to and/or to control the operation of submarine energy consuming device 38 and/or hydrocarbon recovery equipment 40.

Communication port 260 may include any suitable structure that is configured to provide information, data, and/or another form of communication between internal volume 215 and the exterior of external shell 210. This may include any suitable control signal and/or sensor signal that may be provided to and/or produced by electronic equipment 220. Illustrative, non-exclusive examples of communication port 260 according to the present disclosure include an electrical communication port and/or a fiber optic communication port. It is within the scope of the present disclosure that communication port 260 may include a plurality of communication ports 260 and/or that communication port 260 may form a portion of one or more electrical ports 250 associated with PCEA 200.

Pressure compensation system 238 may include any suitable structure that is configured to control an internal pressure within PCEA 200, to decrease a pressure differential between the internal pressure and an external pressure of the submarine environment proximal to the PCEA, to minimize the pressure differential, to eliminate the pressure differential, to control the internal pressure to be substantially equal to the external pressure, and/or to maintain the pressure differential below a threshold level. The use of pressure compensation system 238 may decrease the pressure differential, thereby decreasing a magnitude of the hydrostatic forces that act upon PCEA 200 and/or external shell 210 due to this pressure differential, and providing for the use of thinner, lighter, and/or cheaper materials in the construction of PCEA 200 and/or external shell 210 than might be utilized if PCEA 200 did not include and/or was not in communication with pressure compensation system 238.

Pressure compensation system 238 includes or is in fluid communication with at least one pressure compensation port 240 that provides fluid communication between internal volume 215 and a pressure compensation device 242. Pressure compensation device 242 may include any suitable structure that is configured to control the internal pressure of PCEA 200. As an illustrative, non-exclusive example, it is within the scope of the present disclosure that pressure compensation device 242 may include a variable volume device 244, illustrative, non-exclusive examples of which include a bellows, an elastic bladder, and/or a piston and cylinder.

It is within the scope of the present disclosure that internal volume 215 may include or contain a fluid 246. When internal volume 215 includes fluid 246, pressure compensation system 238 may control and/or provide for a flow of fluid 246 between internal volume 215 and variable volume device 244 to control the pressure differential. It is within the scope of the present disclosure that fluid 246 may include an incompressible, or at least substantially incompressible fluid, such as a liquid 248. The use of an incompressible fluid such as liquid 248 may provide additional support for an external surface of external shell 210 against the hydrostatic forces that may act on PCEA 200 when the pressure differential is nonzero. However, it is also within the scope of the present disclosure that fluid 246 may include a compressible fluid, such as a gas.

Thermal management system 265 may include and/or be in fluid communication with a thermal management fluid outlet port 270 that is configured to produce an outlet stream 272 of thermal management fluid 274 from internal volume 215 of PCEA 200 and provide the outlet stream to a thermal management device 276. Thermal management device 276 is configured to control, change, modify, decrease, or otherwise adjust a temperature of outlet stream 272 to produce a temperature-controlled thermal management fluid stream 278. The temperature-controlled thermal management fluid stream may be supplied through a thermal management fluid inlet port 280 to internal volume 215 to control the temperature of at least a portion of PCEA 200, electronic equipment 220, and/or internal volume 215.

Thermal management device 276 may include any suitable structure that is configured to change the temperature of and/or provide a motive force to thermal management fluid 274 that flows therethrough. Illustrative, non-exclusive examples of thermal management device 276 according to the present disclosure include any suitable heat exchange device 282, illustrative, non-exclusive examples of which include a heat exchanger, a radiator, a condenser coil, and/or an air conditioner. Additional illustrative, non-exclusive examples of components of thermal management device 276 include any suitable pump 283, compressor, blower, fan, valve, and/or orifice. Thus, thermal management device 276 may be configured to circulate thermal management fluid in heat exchange relationship between at least a portion of internal volume 215 and/or electronic equipment 220 and thermal management device 276.

Thermal management fluid 274 may include any suitable fluid that is configured to transfer thermal energy between internal volume 215 and/or electronic equipment 220 and thermal management device 276. Illustrative, non-exclusive examples of thermal management fluids 274 according to the present disclosure include a gas, air, a liquid, a dielectric liquid, water, antifreeze, ethylene glycol, diethylene glycol, propylene glycol, alcohol, oil, mineral oil, silicon oil, fluorocarbons, and/or refrigerants.

It is within the scope of the present disclosure that thermal management fluid 274 may include, contain, and/or be fluid 246 and/or liquid 248, such as when thermal management fluid 274 is provided to internal volume 215 but is not segregated or otherwise maintained separately from fluid 246. Thus, it is within the scope of the present disclosure that thermal management fluid 274 may be circulated in direct heat exchange relationship between electronic equipment 220 and thermal management device 276. However, it is also within the scope of the present disclosure that thermal management system 265 and/or PCEA 200 may include additional structure configured to segregate and/or maintain thermal management fluid 274 separately from fluid 246.

As an illustrative, non-exclusive example, it is within the scope of the present disclosure that thermal management system 265 and/or PCEA 200 may include conduits 284 that are in fluid communication with thermal management fluid outlet port 270 and/or thermal management fluid inlet port 280, and which are configured to convey the thermal management fluid between thermal management device 276 and an internal heat transfer structure 286 without mixing between the thermal management fluid and fluid 246. Illustrative, non-exclusive examples of internal heat transfer structures 286 according to the present disclosure include any suitable heat transfer plate, radiator, heat exchanger, and/or evaporator coil.

It is within the scope of the present disclosure that electronic equipment 220 may be mounted and/or operatively attached to internal heat transfer structure 286. However, it is also within the scope of the present disclosure that electronic equipment 220 may not be directly mounted to the internal heat transfer structure but may be in thermal communication with the internal heat transfer structure, such as by conducting and/or convecting thermal energy through fluid 246. It is further within the scope of the present disclosure that thermal management system 265 and/or PCEA 200 also may include one or more thermal management fluid distribution structures 288 that are configured to direct and/or focus a flow of the thermal management fluid to and/or on a particular, target, and/or desired portion of electronic equipment 220.

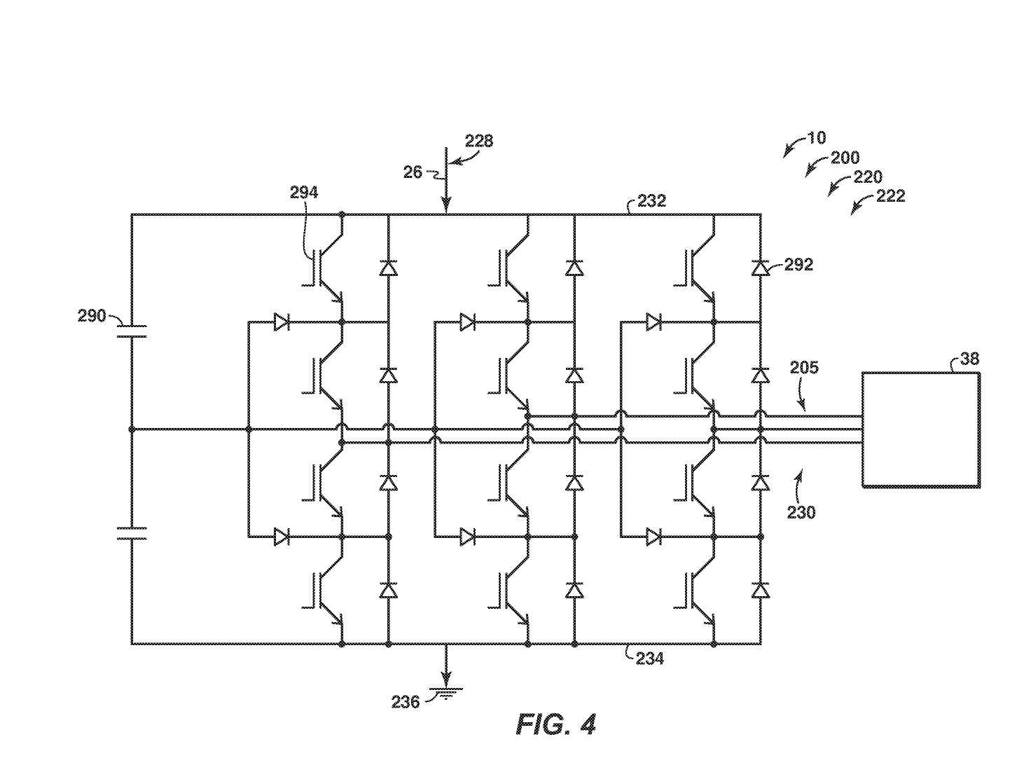

FIG. 4 provides a schematic representation of an illustrative, non-exclusive example of a DC to AC inverter 222 that may form a portion of PCEA 200 and/or electronic equipment 220 according to the present disclosure. DC to AC inverter 222 is configured to receive a DC input 228, such as HVDC electric current 26 of FIGS. 1 and 2, and to produce a three-phase AC output 230, which may be supplied to a submarine energy consuming device 38 as conditioned electric current 205.

DC to AC inverter 222 includes a DC bus 232 that is configured to distribute DC input 228, as well as a ground bus 234 that is connected to a ground 236. The DC to AC inverter also may include a plurality of additional electronic components, including capacitors 290, diodes 292, and/or electrical switches 294, with a representative one of each labeled in FIG. 4. As discussed in more detail herein, it is within the scope of the present disclosure that electronic equipment 220 may include other components in addition to DC to AC inverter 222, that DC to AC inverter 222 may not be included in electronic equipment 220, and/or that a different electrical architecture may be utilized for DC to AC inverter 222.

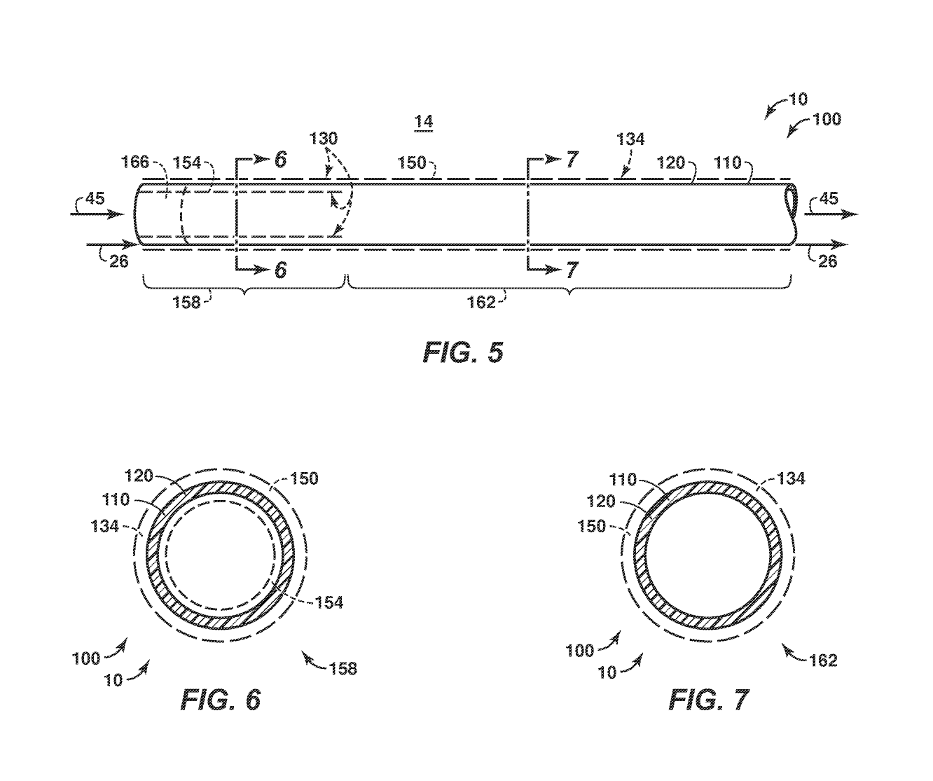

FIG. 5 is a schematic representation of an illustrative, non-exclusive example of submarine hydrocarbon pipeline 100 according to the present disclosure. As discussed in more detail herein, submarine hydrocarbon pipeline 100 includes fluid conduit 110, which is configured to transmit fluid stream 45, and electrical conduit 120, which is configured to transmit electric current 26. As also discussed in more detail herein, submarine hydrocarbon pipeline 100 also may include electrical insulation 130 and/or thermal insulation 134.

As shown in FIG. 5, it is within the scope of the present disclosure that electrical insulation 134 may include external electrical insulation 150 and/or internal electrical insulation 154. External electrical insulation 150 may be configured to electrically isolate a portion, majority, a substantial portion, and/or all of an external surface of submarine hydrocarbon pipeline 100, fluid conduit 110, and/or electrical conduit 120 from electrical communication with submarine environment 14.

Internal electrical insulation 154 may be configured to electrically isolate an isolated portion 158 of an internal surface of submarine hydrocarbon pipeline 100, fluid conduit 110, and/or electrical conduit 120 from electrical communication with fluid stream 45. It is within the scope of the present disclosure that the isolated portion may include a majority, a substantial portion, and/or all of the internal surface of the submarine hydrocarbon pipeline. However, it is also within the scope of the present disclosure that at least an unisolated portion 162 of the internal surface of the submarine hydrocarbon pipeline may not be electrically isolated from the fluid stream.

As an illustrative, non-exclusive example, it is within the scope of the present disclosure that submarine hydrocarbon pipeline 100 may include an end region, an end connector, and/or any suitable coupling 166 configured to connect or otherwise attach the submarine hydrocarbon pipeline to another piece of equipment, illustrative, non-exclusive examples of which include electric current source 20, upstream device 42, fluid distribution module 60, current distribution module 70, PCEA 200, and/or submarine energy consuming device 38 of FIGS. 1-2.

When the submarine hydrocarbon pipeline is connected to another piece of equipment, it is within the scope of the present disclosure that internal electrical insulation 154 may extend within the submarine hydrocarbon pipeline proximal to and/or in the vicinity of coupling 166. As an illustrative, non-exclusive example, it is within the scope of the present disclosure that internal electrical insulation 154 may extend a sufficient distance from coupling 166 to prevent, inhibit, impede, block and/or otherwise decrease a flow of electric current 26 from submarine hydrocarbon pipeline 100 and into the other piece of equipment.

Thus, it is within the scope of the present disclosure that a length, or extent, of insolated portion 158 may be chosen, or selected, based at least in part on a variable associated with the fluid stream, an illustrative, non-exclusive example of which includes the electrical conductivity of the fluid stream. As an illustrative, non-exclusive example, the length of isolated portion 158 that may be utilized when submarine hydrocarbon pipeline 100 is configured to transmit a fluid stream with a low electrical conductivity may be less than a length of isolated portion 158 that may be utilized when submarine hydrocarbon pipeline 100 is configured to transmit a fluid stream with a relatively higher electrical conductivity.

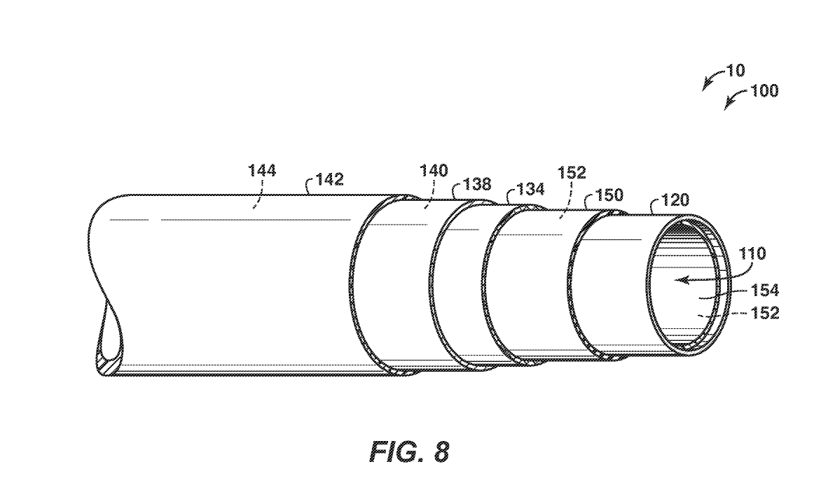

FIG. 6 provides a schematic representation of a cross-sectional view of submarine hydrocarbon pipeline 100 taken along plane 6-6 of FIG. 5 and within isolated portion 158 of the submarine hydrocarbon pipeline. Therein, submarine hydrocarbon pipeline 100 includes both external electrical insulation 150 and internal electrical insulation 154 and also may include thermal insulation 134. Conversely, FIG. 7 provides a schematic representation of a cross-sectional view of the submarine hydrocarbon pipeline of FIG. 5 taken along plane 7-7 and within unisolated portion 162 of the submarine hydrocarbon pipeline. Therein, submarine hydrocarbon pipeline 100 includes external electrical insulation 150, and optionally may include thermal insulation 134, but does not include internal electrical insulation 154.

FIG. 8 provides a less schematic but still illustrative, non-exclusive example of another submarine hydrocarbon pipeline 100 according to the present disclosure. In FIG. 8, submarine hydrocarbon pipeline 100 includes fluid conduit 110, which also serves as electrical conduit 120, and also includes a plurality of additional layers, including abrasion barrier 142, which may include a polyethylene abrasion layer 144, water barrier 138, which may include a lead sheath 140, thermal insulation 134, external electrical insulation 150, which may include fusion-bonded epoxy 152, and internal electrical insulation 154, which also may include fusion-bonded epoxy 152. It is within the scope of the present disclosure that, as discussed in more detail herein, each of the plurality of additional layers may extend across, surround, cover, and/or coat at least a portion of the external surface and/or the internal surface of fluid conduit 110, optionally including a majority, a substantial portion, and/or all of the external surface and/or the internal surface.

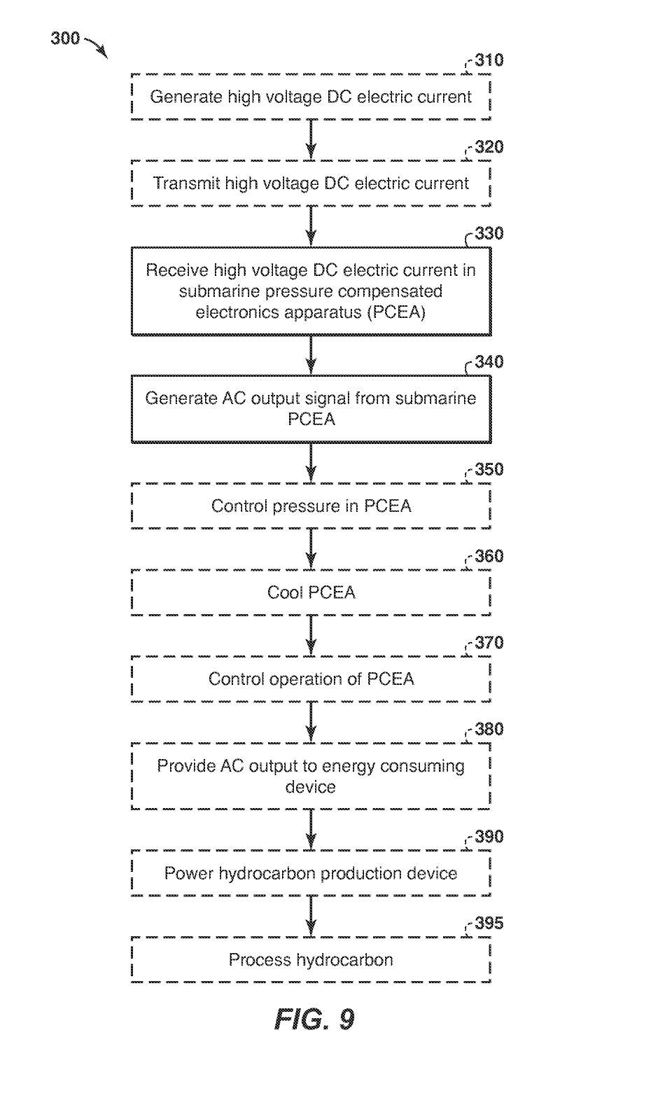

FIG. 9 provides illustrative, non-exclusive examples of methods 300 of utilizing HVDC electric current in a submarine environment. The methods of FIG. 9 optionally include generating a HVDC electric current at 310 and transmitting the HVDC electric current at 320. The methods further include receiving the HVDC electric current in a submarine PCEA at 330 and generating an AC output signal from the submarine PCEA at 340. The methods also may include controlling the pressure within the PCEA at 350, cooling the PCEA at 360, controlling the operation of the PCEA at 370, providing the AC output to an energy consuming device at 380, powering a hydrocarbon production device at 390, and/or processing a hydrocarbon at 395.

Generating the HVDC electric current at 310 may include generating the HVDC electric current using any suitable system, method, and/or mechanism, including the use of the illustrative, non-exclusive examples of electric current source 20 that are discussed in more detail herein. Transmitting the HVDC electric current at 320 may include transmitting the HVDC electric current from the HVDC current source to PCEA 200. Additionally or alternatively, transmitting the HVDC electric current may include transmitting the HVDC electric current in a submarine environment using submarine hydrocarbon pipeline 100.

Receiving the HVDC electric current in a submarine PCEA at 330 may include receiving the HVDC electric current into any suitable submarine PCEA that is configured for use in the submarine environment and that may change, modify, condition, or otherwise adjust the HVDC electric current into a form that may be utilized within the submarine environment. As an illustrative, non-exclusive example, receiving the HVDC electric current may include receiving the HVDC electric current in PCEA 200.

Generating an AC output signal from the submarine PCEA at 340 may include producing the AC output within the PCEA. As an illustrative, non-exclusive example, the generating may include inverting the HVDC electric current to produce an AC electric current. As another illustrative, non-exclusive example, the generating may include inverting the HVDC electric current using DC to AC inverter 222. As another illustrative, non-exclusive example, the generating may include producing a frequency-controlled AC output signal that is configured to control a rotational frequency of an AC electric motor.

Controlling the pressure within the PCEA at 340 may include maintaining a pressure differential between an interior of the PCEA and an exterior of the PCEA to be less than a threshold pressure differential. This may include the use of pressure compensation system 238 to control the pressure differential. Illustrative, non-exclusive examples of threshold pressure differentials according to the present disclosure include threshold pressure differentials of less than 500 kilopascals (kPa), less than 400 kPa, less than 300 kPa, less than 200 kPa, less than 100 kPa, less than 50 kPa, less than 25 kPa, less than 10 kPa, less than 5 kPa, less than 1 kPa, or less than 0.5 kPa.

Cooling the PCEA at 360 may include the use of any suitable structure to decrease an internal temperature of the PCEA and/or to maintain the internal temperature of the PCEA at about a desired temperature and/or within a desired temperature range. As an illustrative, non-exclusive example, the cooling may include the use of thermal management system 265 to cool the PCEA, such as by transferring thermal energy between the internal volume of the PCEA and the submarine environment and/or by pumping the thermal management fluid through the PCEA and/or the thermal management system. It is within the scope of the present disclosure that the cooling may include cooling the entire internal volume of the PCEA; however, it is also within the scope of the present disclosure that the cooling may include cooling a selected portion and/or a cooled region of the PCEA.

Controlling the operation of the PCEA at 370 may include the use of any suitable structure and/or signal to determine a desired output from the PCEA and controlling the operation of the PCEA to produce the desired output. This may include the use of controller 226 and/or communication port 260. As an illustrative, non-exclusive example, the PCEA may receive a control signal and may control the AC output signal based thereon. As another illustrative, non-exclusive example, controlling the operation of the PCEA may include controlling the AC output current produced by the PCEA. As another illustrative, non-exclusive example, controlling the output of the PCEA may include controlling a voltage of the AC output signal. As yet another illustrative, non-exclusive example, controlling the output of the PCEA may include controlling a frequency of the AC output signal.

Providing the AC output to an energy consuming device at 380 may include providing the AC output to any suitable energy consuming device. Illustrative, non-exclusive examples of energy consuming devices according to the present disclosure include submarine energy consuming device 38 and/or hydrocarbon recovery equipment 40. It is within the scope of the present disclosure that the AC output may be configured to control the operation of the energy consuming device, including controlling an operational state of the energy consuming device and/or, when the energy consuming device includes an electric motor, controlling a rotational frequency of the energy consuming device.

Powering a hydrocarbon production device at 390 may include using the energy consuming device to perform mechanical, thermal, and/or chemical work within the submarine environment. As an illustrative, non-exclusive example, and when the energy consuming device includes an electric motor, the electric motor may be utilized to power any suitable piece of hydrocarbon recovery equipment 40. It is within the scope of the present disclosure that hydrocarbon recovery equipment 40 may be utilized to produce, transport, and/or process a hydrocarbon, as shown at 395. It is also within the scope of the present disclosure that the producing, transporting, and/or processing may include the use of submarine hydrocarbon pipeline 100 to transmit a fluid stream that includes the hydrocarbon.

It is within the scope of the present disclosure that at least a portion, a majority, a substantial portion, and/or all of the steps of methods 300 according to the present disclosure, when performed, may be performed within the submarine environment. It is also within the scope of the present disclosure that at least a portion, a majority, a substantial portion, and/or all of the steps of methods 300 according to the present disclosure may be performed simultaneously.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently. It is also within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entity in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” may mean A alone, B alone, C alone, A and B together, A and C together, B and C together, A, B and C together, and optionally any of the above in combination with at least one other entity.

In the event that any references are incorporated by reference herein and define a term in a manner or are otherwise inconsistent with either the non-incorporated portion of the present disclosure or with any of the other incorporated references, the non-incorporated portion of the present disclosure shall control, and the term or incorporated disclosure therein shall only control with respect to the reference in which the term is defined and/or the incorporated disclosure was originally present.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

Illustrative, non-exclusive examples of systems and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A submarine hydrocarbon pipeline configured to transmit a fluid stream and a high voltage DC (HVDC) electric current in a submarine environment, the submarine hydrocarbon pipeline comprising:

an electrically conductive conduit defining a fluid pathway for transmitting the fluid stream and an electrical pathway for transmitting the HVDC electric current.

A2. The submarine hydrocarbon pipeline of paragraph Al, wherein the submarine hydrocarbon pipeline further includes an electrical insulator operatively attached to at least a portion of the electrically conductive conduit.

A3. The submarine hydrocarbon pipeline of paragraph A2, wherein the electrical insulator includes an external electrical insulator configured to electrically isolate at least a portion of an external surface of the submarine hydrocarbon pipeline from electrical contact with the submarine environment, and optionally wherein the external electrical insulator is configured to electrically isolate all of the external surface of the submarine hydrocarbon pipeline from electrical contact with the submarine environment.

A4. The submarine hydrocarbon pipeline of any of paragraphs A2-A3, wherein the electrical insulator includes an internal electrical insulator configured to electrically isolate an isolated portion of an internal surface of the submarine hydrocarbon pipeline from electrical contact with the fluid stream, and optionally wherein the internal electrical insulator is configured to electrically isolate all of the internal surface of the submarine hydrocarbon pipeline from electrical contact with the fluid stream.

A5. The submarine hydrocarbon pipeline of paragraph A4, wherein at least an unisolated portion of the internal surface is not electrically isolated from the fluid stream.

A6. The submarine hydrocarbon pipeline of paragraph A5, wherein the electrically conductive conduit includes an end connector configured to fluidly connect the submarine hydrocarbon pipeline to at least one of hydrocarbon production equipment, hydrocarbon processing equipment, a pump, and a compressor, optionally wherein the isolated portion of the internal surface is proximal the end connector, and further optionally wherein the isolated portion of the internal surface extends a sufficient distance from the end connector to inhibit conduction of the HVDC electric current through the fluid stream.

A7. The submarine hydrocarbon pipeline of any of paragraphs A2-A6, wherein the electrical insulator includes at least one of a coating, a wrap, a cloth, and a sheath.

A8. The submarine hydrocarbon pipeline of any of paragraphs A2-A7, wherein the electrical insulator includes at least one of a polymer, an elastomer, glass, fiberglass, a ceramic, polyethylene, epoxy, and polypropylene.

A9. The submarine hydrocarbon pipeline of any of paragraphs A1-A8, wherein the submarine hydrocarbon pipeline further includes a water barrier, optionally wherein the water barrier surrounds at least a portion of an external surface of the submarine hydrocarbon pipeline, optionally wherein the water barrier surrounds all of the external surface of the submarine hydrocarbon pipeline, and further optionally wherein the water barrier includes a lead sheath.

A10. The submarine hydrocarbon pipeline of any of paragraphs A1-A9, wherein the submarine hydrocarbon pipeline further includes thermal insulation, and optionally wherein the thermal insulation surrounds at least a portion of an external surface of the submarine hydrocarbon pipeline, and further optionally wherein the thermal insulation surrounds a majority of the external surface of the submarine hydrocarbon pipeline, and still further optionally wherein the thermal insulation surrounds all of the external surface of the submarine hydrocarbon pipeline.

A11. The submarine hydrocarbon pipeline of any of paragraphs A1-A10, wherein the fluid stream includes at least one hydrocarbon, and optionally wherein the hydrocarbon includes at least one of oil, natural gas, and liquefied natural gas.

A12. The submarine hydrocarbon pipeline of any of paragraphs A1-A11, wherein the HVDC electric current includes a voltage of at least 0.5 kilovolt (kV), optionally including a voltage of at least 1 kV, at least 1.5 kV, at least 2 kV, at least 5 kV, at least 10 kV, at least 25 kV, at least 50 kV, at least 75 kV, at least 100 kV, at least 150 kV, at least 200 kV, at least 250 kV, at least 300 kV, at least 350 kV, at least 400 kV, at least 450 kV, at least 500 kV, or at least 750 kV.

A13. The submarine hydrocarbon pipeline of any of paragraphs A1-A12, wherein a voltage of the HVDC electric current is sufficient to inhibit corrosion of the submarine hydrocarbon pipeline in the submarine environment.

A14. The submarine hydrocarbon pipeline of any of paragraphs A1-A13, wherein a magnitude of the HVDC electric current is sufficient to generate resistive heating within the electrically conductive conduit, and optionally wherein the resistive heating is sufficient to counteract a heat loss from the fluid stream to the submarine environment, and further optionally wherein the resistive heating is sufficient to maintain a temperature of the fluid stream above a threshold temperature.

A15. The submarine hydrocarbon pipeline of any of paragraphs A1-A14, wherein a power of the HVDC electric current is at least 10 megawatts (MW), optionally including powers of at least 15 MW, at least 20 MW, at least 30 MW, at least 40 MW, at least 50 MW, at least 75 MW, at least 100 MW, at least 150 MW, at least 200 MW, 20-200 MW, 20-50 MW, 100-200 MW, 10-300 MW, or 50-150 MW.

A16. The submarine hydrocarbon pipeline of any of paragraphs A1-A15, wherein the submarine hydrocarbon pipeline is at least 50 km long, optionally wherein the submarine hydrocarbon pipeline is at least 75 km, at least 80 km, at least 100 km, at least 150 km, at least 200 km, at least 250 km, at least 300 km, at least 350 km, at least 400 km, at least 450 km, or at least 500 km long.

A17. The submarine hydrocarbon pipeline of any of paragraphs A1-A16, wherein at least a portion of the submarine hydrocarbon pipeline is located under water, and optionally wherein at least 50%, at least 60%, at least 70%, at least 80%, at least 90%, at least 95%, at least 99%, at least 99.5%, or at least 99.9% of the submarine hydrocarbon pipeline is located under water.

A18. The submarine hydrocarbon pipeline of any of paragraphs A1-A17, wherein the electrically conductive conduit includes a metallic pipe, and optionally wherein the metallic pipe includes a hydrocarbon pipeline configured to transport hydrocarbons.

A19. The submarine hydrocarbon pipeline of any of paragraphs A1-A18, wherein the submarine hydrocarbon pipeline is in electrical communication with a pressure-compensated electronics apparatus, and further wherein the submarine hydrocarbon pipeline supplies the HVDC electric current to the pressure-compensated electronics apparatus.

A20. The submarine hydrocarbon pipeline of paragraph A19, wherein the pressure-compensated electronics apparatus is located in a submarine environment.

A21. The submarine hydrocarbon pipeline of any of paragraphs A19-A20, wherein the pressure-compensated electronics apparatus is configured to produce an AC electric current from the HVDC electric current, and further wherein the pressure-compensated electronics apparatus is configured to supply the AC electric current to a submarine energy-consuming device.

A22. The submarine hydrocarbon pipeline of any of paragraphs A1-A21, wherein the submarine hydrocarbon pipeline is configured to supply at least a portion of the HVDC to an energy-consuming device.

A23. The submarine hydrocarbon pipeline of paragraph A22, wherein the energy-consuming device is configured to consume the portion of the HVDC to perform mechanical work.

A24. The submarine hydrocarbon pipeline of paragraph A23, wherein the energy-consuming device is configured to perform the mechanical work in the submarine environment.

A25. The submarine hydrocarbon pipeline of any of paragraphs A23-A24, wherein the energy-consuming device is configured to perform the mechanical work in at least one of a remote location and a substantially inaccessible location, and optionally wherein the energy-consuming device is configured to perform the work in an arctic environment.

A26. The submarine hydrocarbon pipeline of any of paragraphs A22-A25, wherein the energy-consuming device includes at least one of an electric motor, hydrocarbon production equipment, hydrocarbon processing equipment, a pump, a compressor, a controller, a motor controller, and a sensor.

A27. The submarine hydrocarbon pipeline of any of paragraphs A22-A26, wherein energy-consuming device is configured to provide a motive force to the fluid stream for transmitting the fluid stream through the electrically conductive conduit.

A28. The submarine hydrocarbon pipeline of any of paragraphs A22-A27, wherein the energy-consuming device is configured to at least one of produce the fluid stream and process the fluid stream.

A29. The submarine hydrocarbon pipeline of any of paragraphs A22-A28, wherein the submarine hydrocarbon pipeline is in electrical communication with a DC to AC inverter configured to receive the HVDC and to produce an AC electric current therefrom, and further wherein the energy-consuming device is configured to receive the AC electric current.

B1. A pressure-compensated electronics apparatus for use in a submarine environment, the apparatus comprising:

an external shell that defines an internal volume, wherein the internal volume is isolated from fluid communication with the submarine environment and contains electronic equipment;

at least one electrical port that defines an electrical pathway between the electronic equipment and an electrical device that is outside the external shell; and

a pressure compensation port that defines a fluid pathway between the internal volume and a pressure compensation device that is outside the external shell.

B2. The apparatus of paragraph B1, the apparatus further comprising: a thermal management fluid output port configured to provide a thermal management fluid from the internal volume to a thermal management device that is outside the external shell; and

a thermal management fluid input port configured to receive the thermal management fluid from the thermal management device and into the internal volume.

B3. The apparatus of paragraph B2, wherein the thermal management device includes a heat exchange device configured to exchange thermal energy between the thermal management fluid and the submarine environment.

B4. The apparatus of paragraph B3, wherein the heat exchange device includes at least one of a radiator and a heat exchanger.

B5. The apparatus of any of paragraphs B2-B4, wherein the thermal management device includes a pump configured to circulate the thermal management fluid in heat exchange relationship between at least a portion of the internal volume and the thermal management device.

B6. The apparatus of any of paragraphs B2-B5, wherein the thermal management device is configured to circulate the thermal management fluid in direct heat exchange relationship between the electronic equipment and the thermal management device.

B7. The apparatus of any of paragraphs B2-B6, wherein the apparatus includes a heat transfer plate, wherein at least a portion of the electronic equipment is mounted in heat exchange relationship with the heat transfer plate, and further wherein the thermal management device is configured to circulate the thermal management fluid in heat exchange relationship with the heat transfer plate.

B8. The apparatus of any of paragraphs B2-B7, wherein the thermal management fluid includes a dielectric liquid.

B9. The apparatus of any of paragraphs B1-B8, wherein the apparatus has an internal pressure, wherein the submarine environment proximal to the apparatus has an external pressure, and further wherein the pressure compensation device is configured to decrease a difference between the internal pressure and the external pressure.

B10. The apparatus of paragraph B9, wherein the pressure compensation device is configured to at least one of minimize and eliminate the difference between the internal pressure and the external pressure.

B11. The apparatus of any of paragraphs B1-B10, wherein the pressure compensation device includes a variable volume device, and optionally wherein the variable volume device includes at least one of a bellows, an elastic bladder, and a piston and cylinder.

B12. The apparatus of any of paragraphs B1-B11, wherein the at least one electrical port includes an input electrical port configured to receive an input electrical signal into the apparatus, and an output electrical port configured to provide an output electrical signal from the apparatus.

B13. The apparatus of paragraph B12, wherein the input electrical signal includes a DC electric current, and optionally wherein the input electrical signal includes a high voltage DC electric current.

B14. The apparatus of any of paragraphs B12-B13, wherein the input electrical signal includes an AC electric current, and optionally wherein the input electrical signal includes a high voltage AC electric current.

B15. The apparatus of any of paragraphs B12-B14, wherein the output electrical signal includes an AC output current, optionally wherein the output electrical signal includes a frequency-controlled AC output current, and further optionally wherein the output electrical signal includes a frequency-controlled AC output current configured to control a rotational frequency of an electric motor.

B16. The apparatus of any of paragraphs B1-B15, wherein the electronic equipment includes a DC to AC inverter.

B17. The apparatus of any of paragraphs B1-B16, wherein the electronic equipment includes an AC motor driver, and optionally wherein the AC motor driver includes at least one of an AC motor speed controller, a variable frequency drive, an adjustable speed drive, a variable speed drive, and a vector drive.

B18. The apparatus of any of paragraphs B1-B17, wherein the electronic equipment includes a plurality of electrical switches, and optionally wherein at least a portion of the plurality of electrical switches are solid state electrical switches.

B19. The apparatus of any of paragraphs B1-B18, wherein the electronic equipment includes a plurality of diodes.

B20. The apparatus of any of paragraphs B1-B19, wherein the electronic equipment includes a plurality of capacitors.

B21. The apparatus of any of paragraphs B1-B20, wherein the electronic equipment includes a controller, and optionally wherein the controller is configured to control the operation of a portion of the electronic equipment.

B22. The apparatus of any of paragraphs B1-B21, wherein the apparatus includes a communication port.

B23. The apparatus of paragraph B22, wherein the communication port includes at least one of an electrical communication port and a fiber optic communication port.

B24. The apparatus of any of paragraphs B1-B23, wherein the apparatus includes a modular apparatus configured to be at least one of readily installed, readily repaired, and readily replaced while in the submarine environment.

B25. The apparatus of any of paragraphs B1-B24, wherein the at least one electrical port includes an input electrical port that is configured to receive high voltage DC (HVDC) electric current from a submarine hydrocarbon pipeline.

B26. The apparatus of paragraph B25, wherein at least a portion of the submarine hydrocarbon pipeline is located in a submarine environment.

B27. The apparatus of any of paragraphs B25-B26, wherein the submarine hydrocarbon pipeline is configured to transit a fluid stream and the HVDC electric current.

C1. A submarine power distribution system, the system comprising: the submarine hydrocarbon pipeline of any of paragraphs A1-A29, wherein the submarine hydrocarbon pipeline is in electrical communication with an electric current source; and

the pressure-compensated electronics apparatus of any of paragraphs B1-B27, wherein the pressure-compensated electronics apparatus is in electrical communication with the submarine hydrocarbon pipeline.

C2. The system of paragraph C1, wherein the system further includes the electric current source.

C3. The system of paragraph C2, wherein the electric current source includes a high voltage DC electric current source.

C4. The system of any of paragraphs C2-C3, wherein the electric current source includes an AC electric current source, and further wherein the electric current source includes a rectifier configured to convert AC electric current from the AC electric current source into DC electric current, and optionally wherein the electric current source includes at least one of a transformer, a buck transformer, and a boost transformer, and further optionally wherein the AC electric current source includes a high voltage AC electric current source.

C5. The system of any of paragraphs C1-C4, wherein the system is in electrical communication with an energy-consuming device, and further wherein the energy-consuming device is configured to receive an electrical signal from the pressure-compensated electronics apparatus.

C6. The system of paragraph C5, wherein the energy-consuming device includes at least one of an electric motor, hydrocarbon production equipment, hydrocarbon processing equipment, a pump, a compressor, a controller, a motor controller, and a sensor.

C7. The system of any of paragraphs C5-C6, wherein the energy-consuming device is configured to perform mechanical work with the received electrical signal.

C8. The system of paragraph C7, wherein the energy-consuming device is configured to perform the mechanical work in the submarine environment.

C9. The system of any of paragraphs C7-C8, wherein the energy-consuming device is configured to perform the mechanical work in at least one of a remote location and a substantially inaccessible location, and optionally wherein the energy-consuming device is configured to perform the work in an arctic environment.

C10. The system of any of paragraphs C5-C9, wherein the energy-consuming device is configured to provide a motive force to a fluid stream for transmitting the fluid stream through the submarine hydrocarbon pipeline.

C11. The system of any of paragraphs C5-C10, wherein the energy-consuming device is configured to at least one of produce the fluid stream and process the fluid stream.

C12. The system of any of paragraphs C5-C11, wherein the system includes a plurality of pressure-compensated electronics apparatus and a plurality of energy-consuming devices, and further wherein each of the plurality of energy-consuming devices is in electrical communication with at least one of the plurality of pressure-compensated electronics apparatus.

C13. The system of any of paragraphs C5-C12, wherein the pressure-compensated electronics apparatus is in electrical communication with a motor drive assembly, and further wherein, the motor drive assembly is in electrical communication with the energy-consuming device.

D1. A method of controlling a rotational frequency of an electric motor in a submarine environment, the method comprising:

receiving a high voltage DC (HVDC) electric current with the pressure-compensated electronics apparatus of any of paragraphs B1-B27;

generating a frequency-controlled AC output current with the pressure-compensated electronics apparatus; and

providing the frequency-controlled AC output current to an electric motor.

D2. The method of paragraph D1, wherein the method further includes generating the HVDC electric current.

D3. The method of paragraph D2, wherein the generating includes rectifying a high voltage AC (HVAC) electric current.

D4. The method of any of paragraphs D1-D3, wherein the method further includes transmitting the HVDC electric current with the submarine hydrocarbon pipeline of any of paragraphs A1-A29.

D5. The method of any of paragraphs D1-D4, wherein the method further includes powering a hydrocarbon production device with the electric motor.

D6. The method of any of paragraphs D1-D5, wherein the method further includes at least one of producing a hydrocarbon, transporting a hydrocarbon, and processing a hydro carbon.

D7. The method of any of paragraphs D1-D6, wherein the receiving, the generating, and the providing occur in the submarine environment.

D8. The method of any of paragraphs D1-D7, wherein the method further includes maintaining a difference between a pressure internal to the pressure-compensated electronics apparatus and a pressure external to the pressure-compensated electronics apparatus to be less than a threshold pressure differential, and optionally wherein the threshold pressure differential is less than 500 kilopascals (kPa), optionally including threshold pressure differentials of less than 400 kPa, less than 300 kPa, less than 200 kPa, less than 100 kPa, less than 50 kPa, less than 25 kPa, less than 10 kPa, less than 5 kPa, less than 1 kPa, or less than 0.5 kPa.

D9. The method of any of paragraphs D1-D8, wherein the method further includes cooling at least a cooled region of the internal volume of the pressure-compensated electronics apparatus, and optionally wherein the cooling includes exchanging thermal energy between an interior of the pressure-compensated electronics apparatus and the submarine environment.

D10. The method of paragraph D9, wherein the cooling includes flowing a thermal management fluid in heat exchange relationship with the cooled region and the submarine environment.

D11. The method of paragraph D10, wherein the method further includes pumping the thermal management fluid.

D12. The method of any of paragraphs D1-D11, wherein the method further includes controlling the operation of the pressure-compensated electronics apparatus, optionally wherein controlling the operation of the pressure-compensated electronics apparatus includes controlling the AC output current produced by the pressure-compensated electronics apparatus, and further optionally wherein controlling the operation of the pressure-compensated electronics apparatus includes providing a control signal to the pressure-compensated electronics apparatus and controlling the AC output current based at least in part upon the control signal.

E1. A method of transmitting high voltage DC (HVDC) electric current in a submarine environment, the method comprising:

providing a HVDC electric current from a HVDC electric current source; and

transmitting the HVDC electric current from the HVDC electric current source through the submarine environment using the submarine hydrocarbon pipeline of any of paragraphs A1-A29.

E2. The method of paragraph E1, wherein the method further includes generating the HVDC electric current.

E3. The method of paragraph E2, wherein the generating includes rectifying a high voltage AC (HVAC) electric current.

E4. The method of any of paragraphs E1-E3, wherein the method further includes receiving the HVDC electric current with the pressure-compensated electronics apparatus of any of paragraphs B1-B27.

F1. A method of providing electric current to a submarine hydrocarbon recovery system, the method comprising:

supplying high voltage DC (HVDC) electric current to a submarine hydrocarbon pipeline;

transmitting the HVDC electric current through the submarine hydrocarbon pipeline to a pressure-compensated electronics apparatus; and

inverting the HVDC electric current in the pressure-compensated electronics apparatus to produce an AC electric current.

F2. The method of paragraph F1, wherein the supplying includes providing the HVDC electric current from a HVDC electric current source.

F3. The method of paragraph F2, wherein the HVDC electric current source includes a high voltage AC electric current source and a rectifier.

F4. The method of any of paragraphs F1-F3, wherein the HVDC electric current source includes a voltage of at least 0.5 kilovolt (kV), optionally including a voltage of at least 1 kV, at least 5 kV, at least 10 kV, at least 25 kV, at least 50 kV, at least 75 kV, at least 100 kV, at least 150 kV, at least 200 kV, at least 250 kV, at least 300 kV, at least 350 kV, at least 400 kV, at least 450 kV, at least 500 kV, or at least 750 kV.

F5. The method of any of paragraphs F1-F4, wherein the method further includes providing the AC electric current to hydrocarbon production equipment.

F6. The method of paragraph F5, wherein the method further includes at least one of producing, processing, and transporting a hydrocarbon with the hydrocarbon production equipment.

F7. The method of any of paragraphs F1-F6, wherein the method further includes producing the HVDC electric current, and optionally wherein the producing includes rectifying a high voltage AC electric current.

G1. The use of a submarine hydrocarbon pipeline to transmit fluid and HVDC electric current.

G2. The use, in a submarine environment, of a pressure-compensated electronics apparatus to at least one of provide electric current to and control the operation of an energy-consuming device.

G3. The use of any of the submarine hydrocarbon pipeline of any of paragraphs A1-A29, any of the apparatus of any of paragraphs B1-B27, and/or any of the systems of any of paragraphs C1-C13 with any of the methods of any of paragraphs D1-F7.

G4. The use of any of the methods of any of paragraphs D1-F7 with any of the submarine hydrocarbon pipelines of any of paragraphs A1-A29, any of the apparatus of any of paragraphs B1-B27, and/or any of the systems of any of paragraphs C1-C13.

G5. The use of any of the submarine hydrocarbon pipelines of any of paragraphs A1-A29, any of the apparatus of any of paragraphs B1-B27, any of the systems of any of paragraphs C1-C13, and/or any of the methods of any of paragraphs D1-F7 to at least one of transport, process, and produce hydrocarbons.

G6. The use of any of the submarine hydrocarbon pipelines of any of paragraphs A1-A29, any of the apparatus of any of paragraphs B1-B27, any of the systems of any of paragraphs C1-C13, and/or any of the methods of any of paragraphs D1-F7 to transmit electricity.

G7. The use of the submarine hydrocarbon pipeline of any of paragraphs A1-A29 to transmit fluid and HVDC electric current.

G8. The use of the pressure-compensated electronics apparatus of any of paragraphs B1-B27 to at least one of provide electric current to and control the operation of an energy-consuming device in a submarine environment.

PCT1. A submarine hydrocarbon pipeline configured to transmit a fluid stream and a high voltage DC (HVDC) electric current in a submarine environment, the submarine hydrocarbon pipeline comprising:

an electrically conductive conduit defining a fluid pathway for transmitting the fluid stream and an electrical pathway for transmitting the HVDC electric current.

PCT2. The submarine hydrocarbon pipeline of paragraph PCT1, wherein the submarine hydrocarbon pipeline further includes an electrical insulator operatively attached to at least a portion of the electrically conductive conduit, wherein the electrical insulator includes at least one of a coating, a wrap, a cloth, and a sheath, wherein the electrical insulator includes at least one of a polymer, an elastomer, glass, fiberglass, a ceramic, polyethylene, epoxy, and polypropylene, wherein the submarine hydrocarbon pipeline is configured to supply at least a portion of the HVDC to an energy-consuming device, and further wherein the energy-consuming device is configured to consume the portion of the HVDC to perform mechanical work.

PCT3. A method of transmitting high voltage DC (HVDC) electric current in a submarine environment, the method comprising:

providing a HVDC electric current from a HVDC electric current source; and

transmitting the HVDC electric current from the HVDC electric current source through the submarine environment using the submarine hydrocarbon pipeline of any of paragraphs PCT1-PCT2.

PCT4. The method of paragraph PCT3, wherein the method includes receiving the HVDC electric current with a pressure-compensated electronics apparatus, wherein the method includes generating an AC output current with the pressure-compensated electronics apparatus, wherein the method includes providing the AC output current to an electric motor, and further wherein the method includes powering a hydrocarbon production device with the electric motor.

PCT5. A pressure-compensated electronics apparatus for use in a submarine environment, the apparatus comprising:

an external shell that defines an internal volume, wherein the internal volume is isolated from fluid communication with the submarine environment and contains electronic equipment, and further wherein the electronic equipment includes a DC to AC inverter;

at least one electrical port that defines an electrical pathway between the electronic equipment and an electrical device that is outside the external shell; and

a pressure compensation port that defines a fluid pathway between the internal volume and a pressure compensation device that is outside the external shell.

PCT6. The apparatus of paragraph PCT5, the apparatus further comprising:

a thermal management fluid output port configured to provide a thermal management fluid from the internal volume to a heat exchange device that is outside the external shell, wherein the heat exchange device is configured to exchange thermal energy between the thermal management fluid and the submarine environment; and

a thermal management fluid input port configured to receive the thermal management fluid from the heat exchange device and into the internal volume.

PCT7. The apparatus of any of paragraphs PCT5-PCT6, wherein the apparatus has an internal pressure, wherein the submarine environment proximal to the apparatus has an external pressure, and further wherein the pressure compensation device is configured to decrease a difference between the internal pressure and the external pressure.

PCT8. The apparatus of any of paragraphs PCT5-PCT7, wherein the at least one electrical port includes an input electrical port configured to receive a high voltage DC (HVDC) electric current, and an output electrical port configured to provide a frequency-controlled AC output current that is configured to control a rotational frequency of an electric motor.

PCT9. A method of controlling a rotational frequency of an electric motor in a submarine environment, the method comprising:

receiving a high voltage DC (HVDC) electric current with the pressure-compensated electronics apparatus of paragraph PCT8;

generating a frequency-controlled AC output current with the pressure-compensated electronics apparatus;

providing the frequency-controlled AC output current to an electric motor; and

powering a hydrocarbon production device with the electric motor.

PCT10. The method of paragraph PCT9, wherein the method includes transmitting the HVDC electric current with a submarine hydrocarbon pipeline configured to transmit a fluid stream and the HVDC electric current, and further wherein the method includes transmitting the fluid stream with the submarine hydrocarbon pipeline.

PCT11. The method of any of paragraphs PCT9-PCT10, wherein the method further includes cooling at least a cooled region of the internal volume of the pressure-compensated electronics apparatus, wherein the cooling includes flowing a thermal management fluid in heat exchange relationship with the cooled region and the submarine environment.

PCT12. A submarine power distribution system, the system comprising:

a submarine hydrocarbon pipeline that includes an electrically conductive conduit that defines a fluid pathway for transmitting a fluid stream and an electrical pathway for transmitting the electric current, wherein the submarine hydrocarbon pipeline is in electrical communication with an electric current source; and

a pressure-compensated electronics apparatus, wherein the pressure-compensated electronics apparatus is in electrical communication with the submarine hydrocarbon pipeline.

PCT13. The system of paragraph PCT12, wherein the pressure-compensated electronics apparatus includes an external shell that defines an internal volume, wherein the internal volume is isolated from fluid communication with the submarine environment and contains electronic equipment, wherein the electronic equipment includes a DC to AC inverter, wherein the pressure-compensated electronics apparatus further includes an electrical port and a pressure compensation port, and further wherein the pressure compensation port is in fluid communication with a pressure compensation device.

PCT14. The system of any of paragraphs PCT12-PCT13, wherein the system includes an energy-consuming device in electrical communication with the pressure-compensated electronics apparatus, and further wherein the energy-consuming device includes at least one of an electric motor, hydrocarbon production equipment, hydrocarbon processing equipment, hydrocarbon transportation equipment, a pump, a compressor, a controller, a motor controller, and a sensor.

PCT15. The system of any of paragraphs PCT12-PCT14, wherein the system includes a plurality of pressure-compensated electronics apparatus and a plurality of energy-consuming devices, and further wherein each of the plurality of energy-consuming devices is in electrical communication with at least one of the plurality of pressure-compensated electronics apparatus.

### INDUSTRIAL APPLICABILITY

The systems and methods disclosed herein are applicable to the oil and gas industry.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A submarine hydrocarbon pipeline for transmitting a fluid stream and a high voltage DC (HVDC) electric current, the submarine hydrocarbon pipeline comprising:
an electrically conductive conduit defining a fluid pathway for transmitting the fluid stream and an electrical pathway for transmitting the HVDC electric current.

2. The submarine hydrocarbon pipeline of claim 1, wherein the electrically conductive conduit includes a metallic pipe.

3. The submarine hydrocarbon pipeline of claim 1, wherein the submarine hydrocarbon pipeline further includes an electrical insulator operatively attached to at least a portion of the electrically conductive conduit.

4. The submarine hydrocarbon pipeline of claim 3, wherein the electrical insulator includes an external electrical insulator configured to electrically isolate an external surface of the submarine hydrocarbon pipeline from electrical contact with the submarine environment.

5. The submarine hydrocarbon pipeline of claim 3, wherein the electrical insulator includes an internal electrical insulator configured to electrically isolate an isolated portion of an internal surface of the submarine hydrocarbon pipeline from electrical contact with the fluid stream.

6. The submarine hydrocarbon pipeline of claim 5, wherein at least an unisolated portion of the internal surface is not electrically isolated from the fluid stream.

7. The submarine hydrocarbon pipeline of claim 3, wherein the electrical insulator includes at least one of a coating, a wrap, a cloth, and a sheath, and further wherein the electrical insulator includes at least one of a polymer, an elastomer, glass, fiberglass, a ceramic, polyethylene, epoxy, and polypropylene.

8. The submarine hydrocarbon pipeline of claim 1, wherein the submarine hydrocarbon pipeline further includes a water barrier.

9. The submarine hydrocarbon pipeline of claim 1, wherein the submarine hydrocarbon pipeline further includes thermal insulation.

10. The submarine hydrocarbon pipeline of claim 1, wherein the fluid stream includes at least one hydrocarbon.

11. The submarine hydrocarbon pipeline of claim 1, wherein the submarine hydrocarbon pipeline is configured to supply at least a portion of the HVDC to an energy-consuming device, and further wherein the energy-consuming device is configured to consume the portion of the HVDC to perform mechanical work.

12. A method of transmitting high voltage DC (HVDC) electric current in a submarine environment, the method comprising:
providing a HVDC electric current from a HVDC electric current source; and
transmitting the HVDC electric current from the HVDC electric current source through the submarine environment using the submarine hydrocarbon pipeline of claim 1.

13. The method of claim 12, wherein the method includes receiving the HVDC electric current with a pressure-compensated electronics apparatus, wherein the method includes generating an AC output current with the pressure-compensated electronics apparatus, wherein the method includes providing the AC output current to an electric motor, and further wherein the method includes powering a hydrocarbon production device with the electric motor.

14. A pressure-compensated electronics apparatus for use in a submarine environment, the apparatus comprising:
an external shell that defines an internal volume, wherein the internal volume is isolated from fluid communication with the submarine environment and contains electronic equipment, and further wherein the electronic equipment includes a DC to AC inverter;
at least one electrical port that defines an electrical pathway between the electronic equipment and an electrical device that is outside the external shell; and
a pressure compensation port that defines a fluid pathway between the internal volume and a pressure compensation device that is outside the external shell.

15. The apparatus of claim 14, the apparatus further comprising:
a thermal management fluid output port configured to provide a thermal management fluid from the internal volume to a heat exchange device that is outside the external shell, wherein the heat exchange device is configured to exchange thermal energy between the thermal management fluid and the submarine environment; and
a thermal management fluid input port configured to receive the thermal management fluid from the heat exchange device and into the internal volume.

16. The apparatus of claim 15, wherein the apparatus is configured to circulate the thermal management fluid in direct heat exchange relationship with the electronic equipment and the heat exchange device.

17. The apparatus of claim 15, wherein the apparatus includes a heat transfer plate that is in thermal communication with at least a portion of the electronic equipment, and further wherein the apparatus is configured to circulate the thermal management fluid in heat exchange relationship with the heat transfer plate.

18. The apparatus of claim 14, wherein the apparatus has an internal pressure, wherein the submarine environment proximal to the apparatus has an external pressure, and further wherein the pressure compensation device is configured to decrease a difference between the internal pressure and the external pressure.

19. The apparatus of claim 14, wherein the electronic equipment includes an AC motor speed controller.

20. The apparatus of claim 14, wherein the apparatus includes a communication port, and further wherein the communication port includes at least one of an electrical communication port and a fiber optic communication port.

21. The apparatus of claim 14, wherein the at least one electrical port includes an input electrical port configured to receive a high voltage DC (HVDC) electric current, and an output electrical port configured to provide a frequency-controlled AC output current that is configured to control a rotational frequency of an electric motor.

22. A method of controlling a rotational frequency of an electric motor in a submarine environment, the method comprising:
receiving a high voltage DC (HVDC) electric current with the pressure-compensated electronics apparatus of claim 21;
generating a frequency-controlled AC output current with the pressure-compensated electronics apparatus;
providing the frequency-controlled AC output current to an electric motor; and
powering a hydrocarbon production device with the electric motor.

23. The method of claim 22, wherein the method includes transmitting the HVDC electric current with a submarine hydrocarbon pipeline configured to transmit a fluid stream and the HVDC electric current, and further wherein the method includes transmitting the fluid stream with the submarine hydrocarbon pipeline.

24. The method of claim 22, wherein the method further includes cooling at least a cooled region of the internal volume of the pressure-compensated electronics apparatus, wherein the cooling includes flowing a thermal management fluid in heat exchange relationship with the cooled region and the submarine environment.

25. A submarine power distribution system, the system comprising:
a submarine hydrocarbon pipeline that includes an electrically conductive conduit that defines a fluid pathway for transmitting a fluid stream and an electrical pathway for transmitting the electric current, wherein the submarine hydrocarbon pipeline is in electrical communication with an electric current source; and
a pressure-compensated electronics apparatus, wherein the pressure-compensated electronics apparatus is in electrical communication with the submarine hydrocarbon pipeline.

26. The system of claim 25, wherein the pressure-compensated electronics apparatus includes an external shell that defines an internal volume, wherein the internal volume is isolated from fluid communication with the submarine environment and contains electronic equipment, wherein the electronic equipment includes a DC to AC inverter, wherein the pressure-compensated electronics apparatus includes at least one electrical port that defines an electrical pathway between the electronic equipment and the submarine hydrocarbon pipeline, and further wherein the pressure-compensated electronics apparatus includes a pressure compensation port that defines a fluid pathway between the internal volume and a pressure compensation device that is outside the external shell.

27. The system of claim 25, wherein the system includes an energy-consuming device in electrical communication with the pressure-compensated electronics apparatus, and further wherein the energy-consuming device includes at least one of an electric motor, hydrocarbon production equipment, hydrocarbon processing equipment, hydrocarbon transportation equipment, a pump, a compressor, a controller, a motor controller, and a sensor.

28. The system of claim 25, wherein the system includes a plurality of pressure-compensated electronics apparatus and a plurality of energy-consuming devices, and further wherein each of the plurality of energy-consuming devices is in electrical communication with at least one of the plurality of pressure-compensated electronics apparatus.
